(19) United States
(12) Patent Application Publication
(10) Pub. No.: US 2025/0316516 A1
(43) Pub. Date: Oct. 9, 2025

(54) SUBSTRATE LOADER AND FRAME ASSEMBLY

(71) Applicant: APPLIED MATERIALS, INC., Santa Clara, CA (US)

(72) Inventors: Srinivas Poshatrahalli Gopalakrishna, Bengaluru (IN); Paul Benjamin Reuter, Austin, TX (US); Devendra Channappa Holeyannavar, Bangalore (IN); Sushant Koshti, Sunnyvale, CA (US); Sandesh Doddamane Ramappa, Bangalore (IN)

(21) Appl. No.: 18/628,430

(22) Filed: Apr. 5, 2024

(51) Int. Cl. H01L 21/677; B25J 11/00; H01L 21/67

(52) U.S. Cl. CPC H01L 21/67772; B25J 11/0095; H01L 21/67259; H01L 21/67766

(57) ABSTRACT

A system includes a frame configured to couple to a factory interface. The frame forms a door opening. The system further includes a substrate cassette loader supported by the frame. The substrate cassette loader includes a base portion coupled to the frame and a support portion. The support portion is configured to support a substrate cassette. The support portion is further configured to move between a first open position and a first closed position. The system further includes a door configured to actuate between a second closed position and a second open position within the door opening. When the door is in the second open position, one or more substrates in a cassette supported within the support portion are accessible via the door opening.

### TECHNICAL FIELD

Embodiments of the present disclosure relate, in general, to a substrate loader and frame assembly, and in particular to a substrate loader and frame assembly for a substrate processing system.

### BACKGROUND

An electronic device manufacturing system can include one or more tools or components for transporting, handling, and processing substrates. Such tools or components can include a factory interface (e.g., an equipment front-end module (EFEM)) connected to a load lock and/or transfer chamber. In some instances, a load lock is configured to handle only one size of substrates. To handle smaller-than-normal substrates, adapters are used in the load lock. This arrangement can be inefficient and/or ineffective.

### SUMMARY

In an aspect of the disclosure, a system includes a frame configured to couple to a factory interface. The frame forms a door opening. The system further includes a substrate cassette loader supported by the frame. The substrate cassette loader includes a base portion coupled to the frame and a support portion. The support portion is configured to support a substrate cassette. The support portion is further configured to move between a first open position and a first closed position. The system further includes a door configured to actuate between a second closed position and a second open position within the door opening. When the door is in the second open position, one or more substrates in a cassette supported within the support portion are accessible via the door opening.

In another aspect of the disclosure, a system includes an adapter frame configured to couple to a factory interface. The system further includes a substrate cassette loader supported by the frame. The system further includes a door configured to actuate between a closed position and an open position within a door opening formed by the adapter frame. The system further includes one or more sensors and a controller configured to cause actuation of the door based on sensor data received from the one or more sensors.

In a further aspect of the disclosure, a system includes a frame forming a door opening. The system further includes a substrate cassette loader coupled to the frame. The substrate cassette loader includes a base portion and a support portion configured to support a substrate cassette and further configured to move between a first open position and a first closed position. The system further includes a door configured to actuate between a second closed position and a second open position. The system further includes a clamp coupled to the door and configured to engage the support portion and lock the support portion in the first closed position when the door is in the second open position.

### BRIEF DESCRIPTION OF THE DRAWINGS

The present disclosure is illustrated by way of example, and not by way of limitation, in the figures of the accompanying drawings in which like references indicate similar elements. It should be noted that different references to “an” or “one” embodiment in this disclosure are not necessarily to the same embodiment, and such references mean at least one.

FIG. 1A is a top schematic view of an example electronic device manufacturing system, according to aspects of the present disclosure.

FIG. 1B is a front schematic view of an example electronic device manufacturing system, according to aspects of the present disclosure.

FIG. 2A is a simplified perspective view of an example substrate loader and frame assembly, according to aspects of the present disclosure.

FIG. 2B is a simplified partial cutaway side view of an example substrate loader and frame assembly, according to aspects of the present disclosure.

FIG. 2C is a simplified perspective view of an example substrate loader frame assembly, according to aspects of the present disclosure.

FIG. 3A is a simplified perspective view of an example substrate loader and frame assembly, according to aspects of the present disclosure.

FIG. 3B is a simplified partial cutaway side view of an example substrate loader and frame assembly, according to aspects of the present disclosure.

FIGS. 3C-3D are simplified partial cutaway side views of an example substrate loader frame assembly, according to aspects of the present disclosure.

FIGS. 4A-4D are simplified partial cutaway side views showing the operation of an example substrate loader and frame assembly, according to aspects of the present disclosure.

FIG. 5 is a simplified schematic diagram of an example control system for a substrate processing system having an example substrate loader and frame assembly, according to aspects of the present disclosure.

FIG. 6 is a flow chart of a method of operating an example substrate loader and frame assembly, according to aspects of the present disclosure.

### DETAILED DESCRIPTION OF EMBODIMENTS

Embodiments described herein cover systems and methods related to a substrate loader and frame assembly for coupling the loader to a factory interface (e.g., an equipment front-end module (EFEM)).

Typically, substrate processing systems are configured to process a given size of substrates (e.g., 300 mm diameter substrates, etc.). To process smaller substrates (e.g., 150 mm or 200 mm diameter substrates, etc.), adapters are put in place so that the system can handle the smaller substrates. For example, a load port coupled to a factory interface and/or a substrate carrier docked at the load port are modified with adapters so that the load port and/or substrate carrier can properly handle smaller sized substrates. These adapters add complexity to current load port operation. For instance, adapters necessitate the use of more complex interlocks to verify correct placement of substrates within the substrate carrier docked to the load port and correct operation of the load port. Additionally, the adapters necessitate complicated procedures to properly install the adapters and verify correct operation of the load port and/or substrate carrier with the adapters. Furthermore, use of adapters slows down production because of the extra time involved in installation and verification. Without using extra time to properly set up a conventional system using the adapters, errors can be introduced into the handling and/or processing of the substrates. As demand for smaller sized substrates (e.g., 150 mm or 200 mm diameter substrates, etc.) increases, a simplified system to replace a conventional load port and/or substrate carrier without the use of conventional adapters would be beneficial.

Aspects and implementations of the instant disclosure address the above-described and other shortcomings of conventional systems by providing a substrate loader and frame that can be adapted to a conventional factory interface (e.g., an EFEM) without the adapters conventionally used in a load port and/or substate carrier. Systems described herein may simplify the handling of smaller sized substrates for a factory interface configured to handle larger sized substrates. Systems described herein may independently work with a factory interface, and may eliminate a conventional load port from a substrate processing system. In some embodiments, the systems described herein allow a factory interface to be adapted for handling substrates having less than a threshold size. For example, the systems described herein may allow a factory interface configured for 300 mm substrates to additionally or alternatively handle 150 mm diameter and/or 200 mm diameter substrates without conventionally-used adapters.

The systems described herein may be independent assemblies having communication with a factory interface server (e.g., controller, etc.) for operating the systems. Additionally, systems described herein may have provisions for integrating sensors such as vibration sensor(s), particle measuring sensor(s), environmental measuring sensor(s), and/or substrate mapping sensor(s).

In some embodiments, a system includes a frame that is configured to couple to a factory interface. The frame may couple to an opening in the factory interface where a conventional load port would ordinarily couple. In some embodiments, the frame forms a door opening. The interior of the factory interface may be accessible via the door opening when a door is open. In some embodiments, the frame is a sheet metal frame formed to fit onto the factory interface.

In some embodiments, the system further includes a substrate cassette loader. The substrate cassette loader may be supported by the frame. In some embodiments, a shelf protrudes from the frame and the substrate cassette loader is to sit on the shelf. In some embodiments, the substrate cassette loader includes a base portion that is coupled to the frame. The base portion may be rigid with respect to the frame (e.g., does not move relative to the frame when coupled thereto). In some embodiments, the substrate cassette loader includes a support portion that is configured to support a substrate cassette. A substrate cassette may form multiple slots for holding and/or supporting multiple substrates. The base portion may include a housing that at least partially envelops the support portion. In some embodiments, the support portion is configured to move between an open position and a closed position. While the support portion is in the closed position, the housing of the base portion at least partially encloses the substrate cassette within the interior space of the substrate cassette loader. While the support portion is in the open position, the substrate cassette can be loaded or unloaded from the support portion. The support portion may form a hinged door that can be opened and closed (e.g., by a user such as a technician, etc.) for loading or unloading substrates.

In some embodiments, the system includes a door that is to actuate between a closed position and an open position within the door opening formed by the frame. When in the closed position, the door may at least partially isolate the interior of the factory interface from the outside environment. When the door is in the open position (and the substrate cassette loader support portion is in the closed position), substrates supported in the substrate cassette loader support portion are accessible via the door opening. For example, a substrate-handling robot may retrieves substrates from the substrate cassette loader (e.g., through the door opening) when the door is in the open position. In some embodiments, a clamp is coupled to the door to engage the substrate cassette loader (e.g., the support portion of the substrate cassette loader) when the door is in the open position. The clamp may act as a mechanical interlock so that the substrate cassette loader cannot be opened when substrates are being retrieved from or placed in the substrate cassette loader.

Embodiments of the present disclosure provide advantages over conventional systems described above. Particularly, some embodiments described herein provide a simplified system for handling smaller sized substrates than a factory interface is configured for and that are conventionally handled using complex adapters. Some advantages of systems described herein include reduced operation time that will increase system throughput. When compared to conventional methods of handling smaller sized substrates by a factory interface configured to handle larger substrates, a system as described herein may be faster to set up and/or operate. Another advantage may include simplified interlock features that reduce overall system complexity which will reduce system cost and system downtime due to unscheduled maintenance, etc. Moreover, a system as described herein may be simpler and/or easier to install and operate compared to conventional systems and methods which will further reduce cost and may provide greater system throughput.

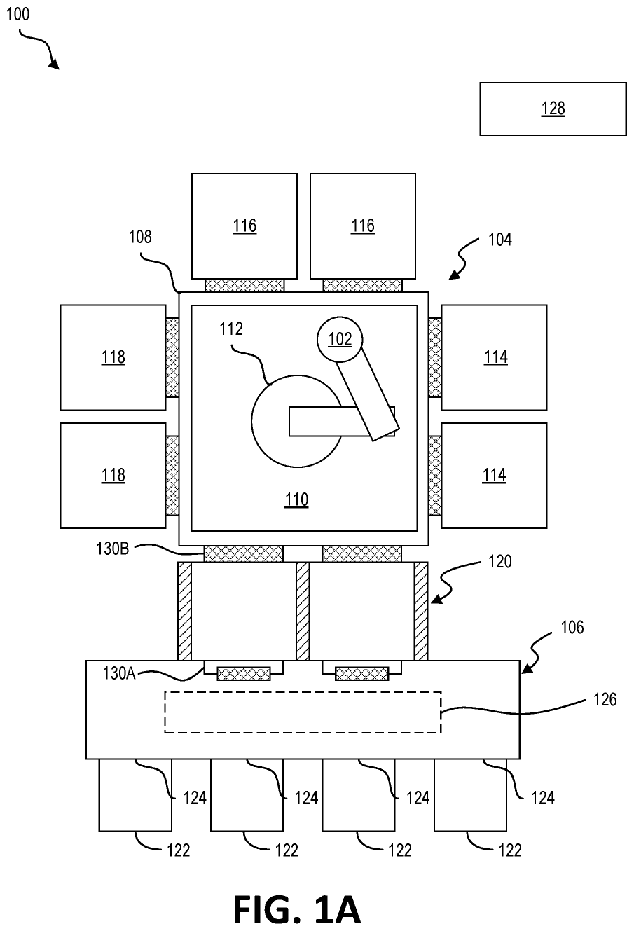

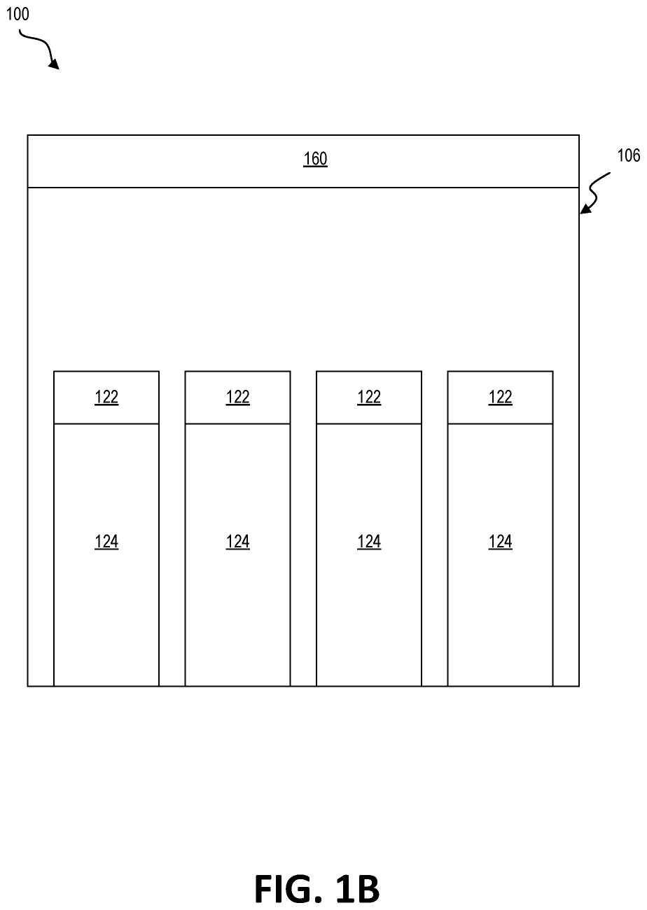

FIGS. 1A and 1B describe an electronic device manufacturing system 100 where one or more load ports are coupled to a factory interface 106. FIG. 1A is a top schematic view of the example electronic device manufacturing system 100, according to aspects of the present disclosure. FIG. 1B is a front schematic view of the example electronic device manufacturing system 100, according to aspects of the present disclosure. It is noted that FIGS. 1A and 1B are used for illustrative purposes, and that different component can be positioned in different location in relation to each view.

Electronic device manufacturing system 100 (also referred to as an electronics processing system) is configured to perform one or more processes on a substrate 102. Substrate 102 can be any suitably rigid, fixed-dimension, planar article, such as, e.g., a silicon-containing disc or wafer, a patterned wafer, a glass plate, or the like, suitable for fabricating electronic devices or circuit components thereon.

Electronic device manufacturing system 100 includes a process tool (e.g., a mainframe) 104 and a factory interface 106 (e.g., an EFEM) coupled to process tool 104. Process tool 104 includes a housing 108 having a transfer chamber 110 therein. Transfer chamber 110 includes one or more processing chambers (also referred to as process chambers) 114, 116, 118 disposed therearound and coupled thereto. Processing chambers 114, 116, 118 can be coupled to transfer chamber 110 through respective ports, such as slit valves or the like.

Processing chambers 114, 116, 118 can be adapted to carry out any number of processes on substrates 102. A same or different substrate process can take place in each processing chamber 114, 116, 118. Examples of substrate processes include atomic layer deposition (ALD), physical vapor deposition (PVD), chemical vapor deposition (CVD), etching, annealing, curing, pre-cleaning, metal or metal oxide removal, or the like. In one example, a PVD process is performed in one or both of process chambers 114, an etching process is performed in one or both of process chambers 116, and an annealing process is performed in one or both of process chambers 118. Other processes can be carried out on substrates therein. Processing chambers 114, 116, 118 can each include a substrate support assembly. The substrate support assembly can be configured to hold a substrate in place while a substrate process is performed.

Transfer chamber 110 also includes a transfer chamber robot 112. Transfer chamber robot 112 can include one or multiple arms where each arm includes one or more end effectors at the end of each arm. The end effector can be configured to handle particular objects, such as wafers. Alternatively, or additionally, the end effector is configured to handle objects such as process kit rings. In some embodiments, transfer chamber robot 112 is a selective compliance assembly robot arm (SCARA) robot, such as a 2-link SCARA robot, a 3-link SCARA robot, a 4-link SCARA robot, and so on.

A load lock 120 can also be coupled to housing 108 and transfer chamber 110. Load lock 120 can be configured to interface with, and be coupled to, transfer chamber 110 on one side and factory interface 106 on another side. Load lock 120 can have an environmentally-controlled atmosphere that is changed from a vacuum environment (where substrates are transferred to and from transfer chamber 110) to an at or near atmospheric-pressure inert-gas environment (where substrates are transferred to and from factory interface 106) in some embodiments. In some embodiments, load lock 120 is a stacked load lock having a pair of upper interior chambers and a pair of lower interior chambers that are located at different vertical levels (e.g., one above another). In some embodiments, the pair of upper interior chambers are configured to receive processed substrates from transfer chamber 110 for removal from process tool 104, while the pair of lower interior chambers are configured to receive substrates from factory interface 106 for processing in process tool 104. In some embodiments, load lock 120 is configured to perform a substrate process (e.g., an etch or a pre-clean) on one or more substrates 102 received therein.

Factory interface 106 can be any suitable enclosure, such as, e.g., an Equipment Front End Module (EFEM). Factory interface 106 can be configured to receive substrates 102 from substrate cassette loaders 122 coupled to various loader frames 124 coupled to factory interface 106. A factory interface robot 126 (shown dotted) can be configured to transfer substrates 102 between substrate cassette loaders 122 and load lock 120. In other and/or similar embodiments, factory interface 106 is configured to receive replacement parts from replacement parts storage containers. Factory interface robot 126 can include one or more robot arms and can be or include a SCARA robot. In some embodiments, factory interface robot 126 has more links and/or more degrees of freedom than transfer chamber robot 112. Factory interface robot 126 can include an end effector on an end of each robot arm. The end effector can be configured to pick up and handle specific objects, such as wafers. Alternatively, or additionally, the end effector can be configured to handle objects such as process kit rings. Any conventional robot type can be used for factory interface robot 126. Transfers can be carried out in any order or direction. Factory interface 106 can be maintained in, e.g., a slightly positive-pressure non-reactive gas environment (using, e.g., nitrogen, other inert gasses, or air with controlled sub-component parameters as the non-reactive gas) in some embodiments.

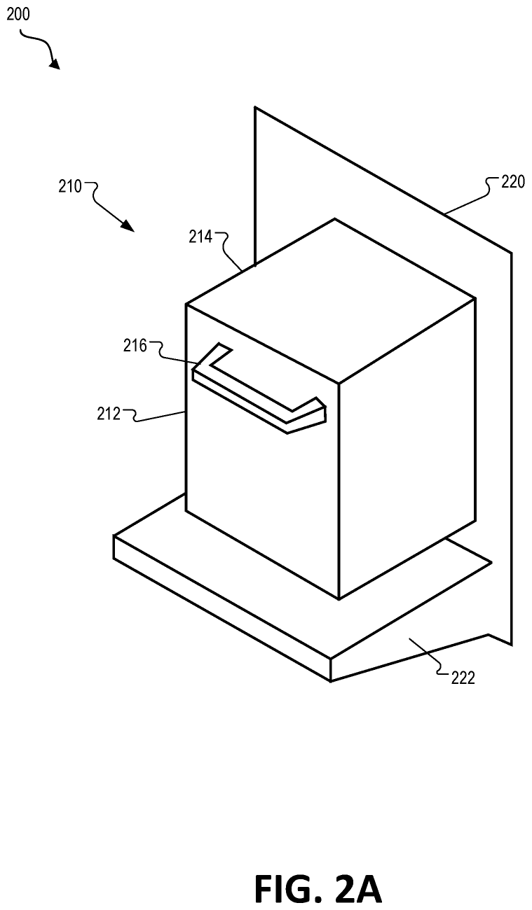

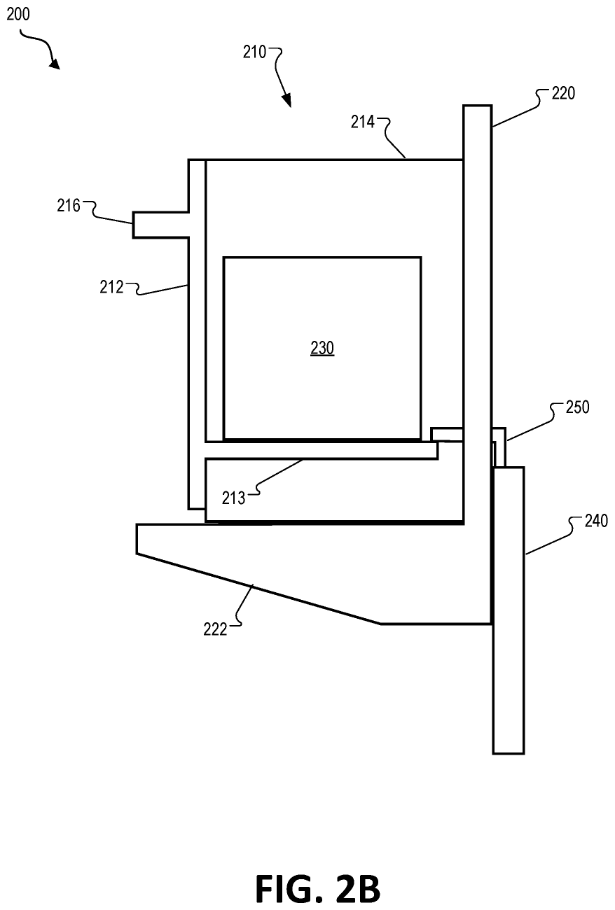

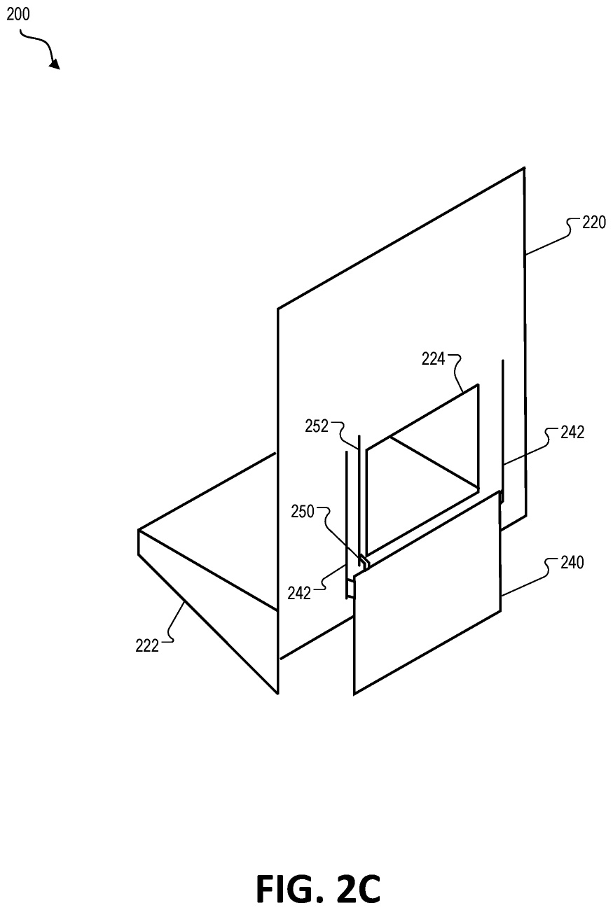

Factory interface 106 can be configured with any number of loader frames 124, which can be located at one or more sides of the factory interface 106 and at the same or different elevations. One or more loader frames 124 can form a door opening so that substrates disposed in substrate cassette loaders 122 can be accessed by factory interface robot 126. Further details regarding the substrate cassette loaders 122 and the loader frames 124 are discussed herein below with respect to FIGS. 2A-6.

Factory interface 106 can include one or more auxiliary components (not shown). The auxiliary components can include substrate storage containers, metrology equipment, servers, air conditioning units, etc. A substrate storage container can store substrates and/or substrate carriers (e.g., FOUPs), for example. Metrology equipment can be used to determine property data of the products that were produced by the electronic device manufacturing system 100. In some embodiments, factory interface 106 can include upper compartment 160, as seen in FIG. 1B. Upper compartment 160 can house electronic systems (e.g., servers, air conditioning units, etc.), utility cables, system controller 128, or other components.

In some embodiments, transfer chamber 110, process chambers 114, 116, and 118, and/or load lock 120 are maintained at a vacuum level. Electronics processing system 100 can include one or more vacuum ports that are coupled to one or more stations of electronic device manufacturing system 100. For example, first vacuum ports 130a can couple factory interface 106 to load locks 120. Second vacuum ports 130b can be coupled to load locks 120 and disposed between load locks 120 and transfer chamber 110.

Electronic device manufacturing system 100 can also include a system controller 128. System controller 128 can be and/or include a computing device such as a personal computer, a server computer, a programmable logic controller (PLC), a microcontroller, and so on. System controller 128 can include one or more processing devices, which can be general-purpose processing devices such as a microprocessor, central processing unit, or the like. More particularly, the processing device can be a complex instruction set computing (CISC) microprocessor, reduced instruction set computing (RISC) microprocessor, very long instruction word (VLIW) microprocessor, or a processor implementing other instruction sets or processors implementing a combination of instruction sets. The processing device can also be one or more special-purpose processing devices such as an application specific integrated circuit (ASIC), a field programmable gate array (FPGA), a digital signal processor (DSP), network processor, or the like. System controller 128 can include a data storage device (e.g., one or more disk drives and/or solid state drives), a main memory, a static memory, a network interface, and/or other components. System controller 128 can execute instructions to perform any one or more of the methodologies and/or embodiments described herein. The instructions can be stored on a computer readable storage medium, which can include the main memory, static memory, secondary storage and/or processing device (during execution of the instructions). System controller 128 can include an environmental controller configured to control an environment (e.g., pressure, moisture level, vacuum level, etc.) within factory interface 106. In embodiments, execution of the instructions by system controller 128 causes system controller to perform the methods of one or more of FIG. 6. System controller 128 can also be configured to permit entry and display of data, operating commands, and the like by a human operator.

FIGS. 2A-2C illustrate an example substrate loader and frame assembly 200, according to aspects of the present disclosure. FIG. 2A is a simplified perspective view of an example substrate loader and frame assembly 200, according to aspects of the present disclosure. FIG. 2B is a simplified partial cutaway side view of an example substrate loader and frame assembly 200, according to aspects of the present disclosure. FIG. 2C is a simplified perspective view of an example substrate loader frame assembly 200, according to aspects of the present disclosure. In some embodiments, the substrate loader and frame assembly may comply with SEMI (Semiconductor Equipment and Materials International) standards.

A frame 220 may be configured to couple to a factory interface (e.g., factory interface 106). The frame 220 may include a shelf 222 that protrudes laterally proximate a bottom portion of the frame 220. A substrate cassette loader 210 may sit on the shelf 222. In some embodiments, the substrate cassette loader 210 includes a base portion 214 and a support portion 212. The base portion 214 may include a housing that at least partially encloses the support portion 212 and may at least partially form an interior space of the substrate cassette loader 210 together with the support portion 212. In some embodiments, the substrate cassette loader 210 is coupled to the shelf 222 and/or the frame 220 by the base portion 214.

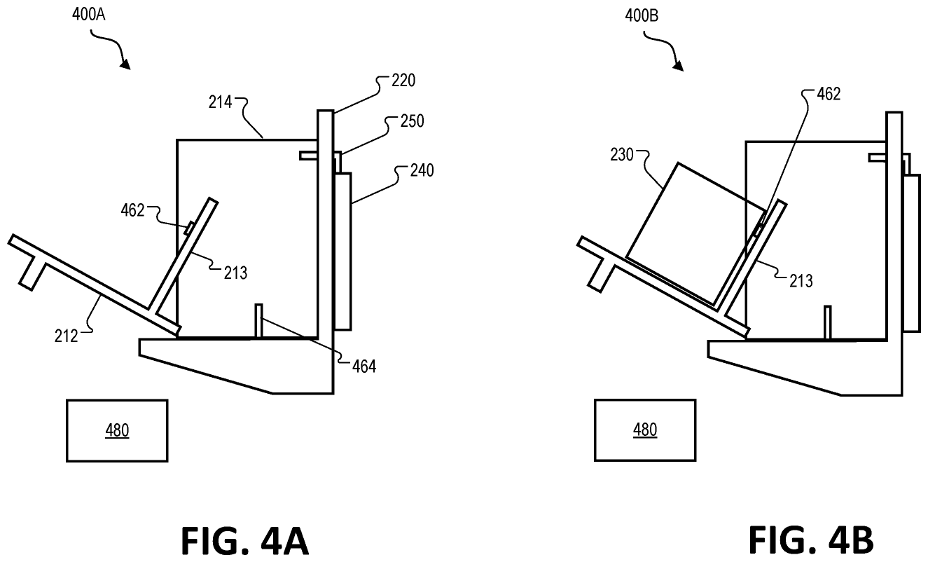

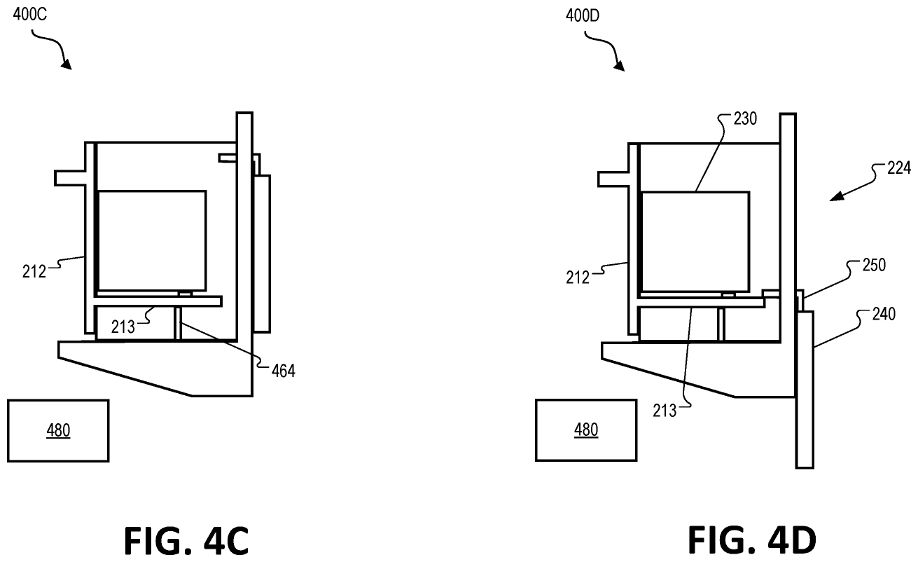

The support portion 212 may include a hinged door having a handle 216. The support portion 212 may pivot with respect to the base portion 214 about an axis of the hinge. The hinge may be positioned proximate a bottom of the support portion 212. The door may be moved between an open position and a closed position. In the closed position, the interior of the substrate cassette loader 210 may be at least partially sealed. Sealing of the interior may combat corrosion. When the door is in the open position, the interior of the substrate cassette loader 210 may be accessible for placement or removal of a substrate cassette 230. In some embodiments, the support portion 212 includes features to support a substrate cassette 230 within the interior region of the substrate cassette loader 210. The substrate cassette 230 may be configured to hold 150 mm diameter and/or 200 mm diameter substrates in an example. In some embodiments, the support portion 212 includes a cassette support 213 to support the substrate cassette 230 within the housing formed by the base portion 214. As is illustrated in FIGS. 4A-4D, the support portion 212 may be coupled to the base portion 214 by a hinge. For example, the support portion 212 may hinge outwards with respect to the base portion 214 to open the interior space of the substrate cassette loader 210 for accessing the substrate cassette 230 and/or for accessing the substrates within the substrate cassette 230. In some embodiments, the substrate cassette loader 210 includes one or more sensors such as a humidity sensor, a temperature sensor, a vibration sensor, etc.

In some embodiments, a door 240 is coupled to the frame 220 opposite the substrate cassette loader 210. The door 240 may be actuatable between an open position (as shown in FIGS. 2B, 2C, and 4D) and a closed position (as shown in FIGS. 4A-4C). The door 240 may be electronically actuated or may be pneumatically actuated. In some embodiments, the door 240 is guided by one or more linear motion guides 242. In some embodiments, two linear motion guides 242 are coupled to the back of the frame 220. The linear motion guides 242 may be coupled on either side of the door opening 224 formed in the frame 220. When the door 240 is in the open position, the interior of the substrate cassette loader 210 may be accessible (e.g., by a substrate-handling robot, etc.) and substrates may be retrieved from or placed in the substate cassette 230. When the door 240 is in the closed position, the interior of the substrate cassette loader 210 may be inaccessible and/or the interior of the factory interface to which the frame 220 is coupled may be isolated. In some embodiments, the door 240 includes a gasket or other seal to seal against the frame 220. In some embodiments, a door guard (not illustrated) may be coupled to the frame 220 to protect the door 240 when the door is in the open position.

In some embodiments, a clamp 250 (e.g., a clamping bar, etc.) is coupled to the door 240. The clamp 250 may be a mechanical interlock to prevent the opening of the substrate cassette loader 210 when the door 240 is in the open position. In some embodiments, the clamp 250 engages the support portion 212 when the door 240 is in the open position. The clamp 250 may engage the cassette support 213. Engagement of the clamp 250 with the support portion 212 may prevent accidental or unintentional access to the interior of the substrate cassette loader 210 when the door 240 is in the open position. Engagement of the clamp 250 with the support portion 212 may prevent the support portion 212 from hinging open and/or may secure the support portion 212 for the placement and/or retrieval of substrates from the substrate cassette 230. In some embodiments, the clamp 250 protrudes through a channel 252 formed in the frame 220. The clamp 250 may rise and fall in the channel 252 as the door 240 is opened and closed.

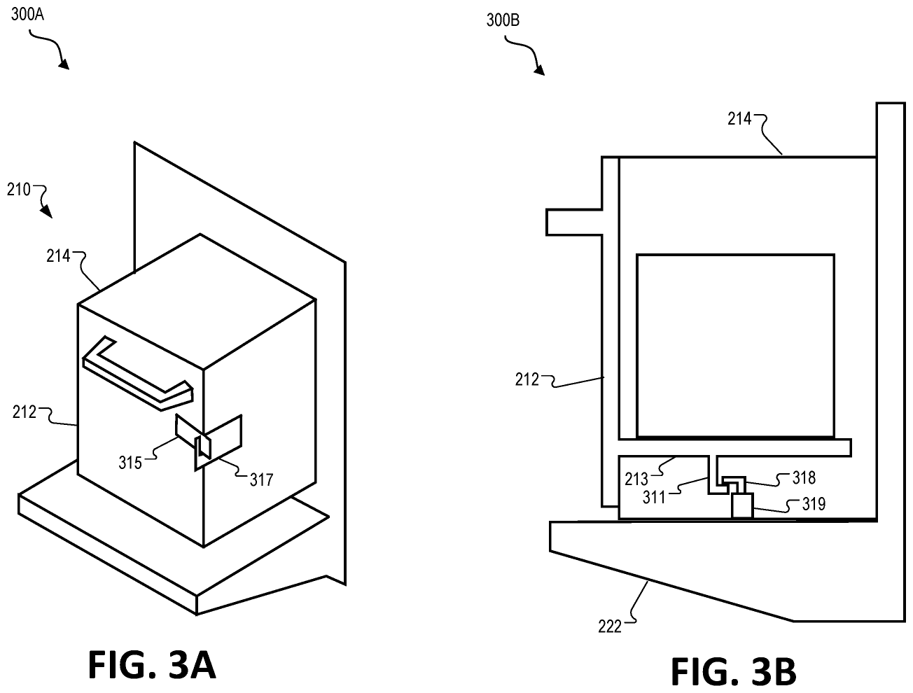

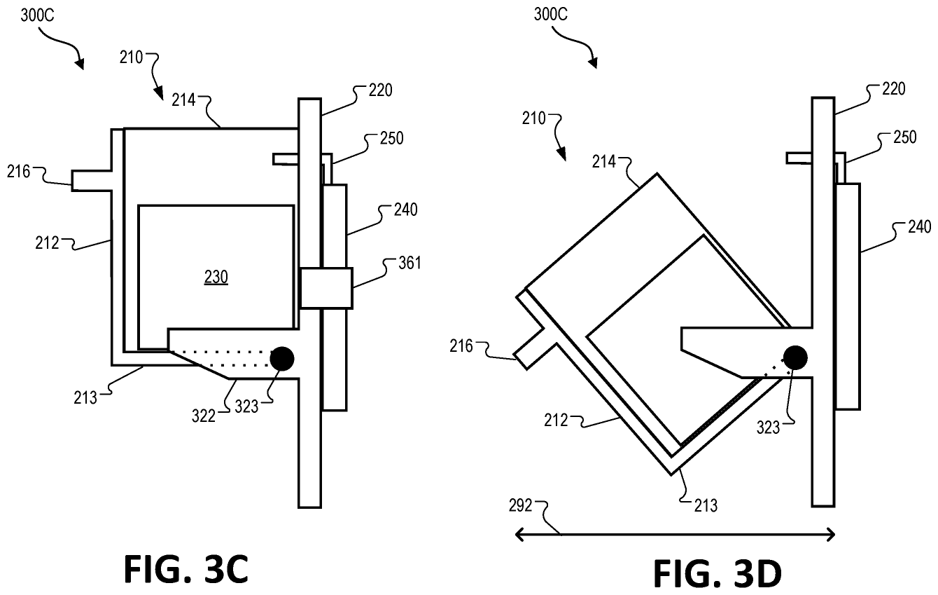

FIG. 3A is a simplified perspective view of an example substrate loader and frame assembly 300A, according to aspects of the present disclosure. In some embodiments, the substrate cassette loader 210 includes a hinged clamp assembly to retain the support portion 212 in the closed position. In some embodiments, a first clamp member 315 coupled to the support portion 212 fits into a slot formed in a second clamp member 317 coupled to the base portion 214. In some embodiments, the first clamp member 315 is coupled to the support portion 212 by a hinge. The first clamp member 315 may be movable by a user (e.g., a technician, etc.). When the support portion 212 is moved to the closed position, the first clamp member 315 may be moved (e.g., via the hinge) to interlock with the second clamp member 317 to retain the support portion 212 in the closed position. To move the support portion 212 to the open position, the first clamp member 315 may be moved to unlock from the second clamp member 317 and the support portion 212 can be opened. In some embodiments, the second clamp member 317 includes a photo micro sensor. The first clamp member 315 may break a light beam of the photo micro sensor when moved to interlock with the second clamp member 317. Sensor data from the photo micro sensor may indicate that the support portion 212 is locked or unlocked (e.g., via the clamp members) based on whether the light beam is broken.

FIG. 3B is a simplified partial cutaway side view of an example substrate loader and frame assembly 300B, according to aspects of the present disclosure. In some embodiments, assembly 300B includes a clamp 318 that engages a flange 311 protruding from the bottom of cassette support 213. The clamp 318 and flange 311 may form a mechanical interlock to secure the support portion 212 in the closed position. An actuator 319 may actuate the clamp 318 to engage the flange 311 to substantially lock the support portion 212 in the closed position. The actuator 319 may be a pneumatic actuator or an electronic actuator. The actuator 319 may be coupled to the shelf 222 or the base portion 214. In some embodiments, the clamp 318 is actuated to engage the flange 311 when the support portion 212 is moved to the closed position. The arrangement of the clamp 318, the flange 311, and the actuator 319 may be included in lieu of or in addition to clamp 250 shown in FIGS. 2A-2C.

FIGS. 3C-3D are simplified partial cutaway side views of an example substrate loader frame assembly 300C, according to aspects of the present disclosure. FIG. 3C shows loader frame assembly 300C in a closed position and FIG. 3D shows loader frame assembly 300C in an open position.

In some embodiments, frame 220 includes a protrusion 322 having a hinge 323 to support the substrate cassette loader 210. In some embodiments, the substrate cassette loader 210 can hinge with respect to the frame 220 about an axis of hinge 323. For example, the substrate cassette loader 210 can be rotated about the hinge 323 to open the interior of the substrate cassette loader. In the closed position (shown in FIG. 3C), the interior of the substrate cassette loader 210 may be at least partially sealed. In the open position (shown in FIG. 3D), the interior of the substrate cassette loader 210 may be accessible (e.g., for loading and/or unloading cassette 230). In some embodiments, the hinge 323 is coupled to the cassette support 213. The protrusion 322 may extend past the hinge 323 to support the sides of the substrate cassette loader 210 as the substrate cassette loader 210 is opened and/or closed. In some embodiments, a sensor 361 is coupled to frame 220. Sensor 361 may sense when the substrate cassette loader 210 is in the closed position.

In some embodiments, the loader frame assembly 300C has a compact design. In some embodiments, the maximum depth 292 of the assembly 300C is less than 350 mm. In some embodiments, the maximum depth 292 of the assembly 300C is less than 340 mm. In some embodiments, the maximum depth 292 of the assembly 300C is approximately 335 mm. The maximum depth 292 of the loader frame assembly 300C may correspond to when the loader is in the open position as shown in FIG. 3D. Comparatively, the assembly 200 may have a maximum depth (e.g., when the support portion 212 is in the open position) of greater than 600 mm. In some embodiments, the maximum depth of the assembly 200 may be approximately 640 mm.

FIGS. 4A-4D are simplified partial cutaway side views showing the operation of an example substrate loader and frame assembly, according to aspects of the present disclosure. Referring to FIG. 4A, a first state 400A of operation of an example substrate loader and frame assembly is shown, according to aspects of the present disclosure. The support portion 212 may be shown in the open position and the door 240 may be shown in the closed position. The clamp 250 may be disengaged from the cassette support 213. In some embodiments, a first sensor 462 positioned on the cassette support 213 may be configured to sense the presence or absence of a cassette 230. In some embodiments, two or more first sensors 462 are positioned on the cassette support 213. In some embodiments, a second sensor 464 positioned within the housing formed by the base portion 214 may be configured to sense whether the support portion 212 is in the closed position. As shown in FIG. 4A, the first sensor 462 may sense that a substrate cassette 230 is not disposed on the support portion 212 and the second sensor 464 may sense that the support portion 212 is not in the closed position. A controller 480 may receive sensor data from the first sensor 462 and the second sensor 464. The controller 480 may control actuation of the door 240 and/or operation of a substrate-handling robot (e.g., a robot to retrieve and/or place substrates in a substrate cassette 230) based on the received sensor data. In some embodiments, the controller 480 may output an indication (e.g., to a graphical user interface (GUI)) indicative of the absence of a substrate cassette 230 and/or that the support portion 212 is not in the closed position.

Referring to FIG. 4B, a second state 400B of operation of an example substrate loader and frame assembly is shown, according to aspects of the present disclosure. A substrate cassette 230 may be placed on the cassette support 213. The first sensor 462 may sense the presence of the substrate cassette 230 and the controller 480 may receive sensor data accordingly. In some embodiments, the first sensor 462 is a photosensor or a plunger sensor. For example, the first sensor 462 may include a plunger that is depressed by a substrate cassette 230 when placed and properly aligned on the cassette support 213. If the substrate cassette 230 is not properly aligned on the cassette support 213, the plunger of the first sensor 462 may not be depressed. Accordingly, the controller 480 may receive sensor data indicating the substrate cassette 230 is not properly placed on the cassette support 213. Where two first sensors 462 are included on the cassette support 213, both sensors are to sense the substrate cassette 230 is properly placed and aligned. If only one first sensor 462 senses the presence of the substrate cassette 230 and the other first sensor 462 does not, the controller 480 may determine the substrate cassette 230 is not properly placed on the cassette support 213. The controller 480 may output an indication (e.g., to a GUI) indicative of the substrate cassette 230 not being properly placed/aligned on the cassette support 213.

Referring to FIG. 4C, a third state 400C of operation of an example substrate loader and frame assembly is shown, according to aspects of the present disclosure. The support portion 212 may be moved to the closed position. The second sensor 464 may sense the support portion 212 is in the closed position and the controller 480 may receive sensor data accordingly. In some embodiments, the second sensor 464 is a photosensor or a plunger sensor. For example, the second sensor 464 may include a plunger that is depressed when the cassette support 213 hinges downward and contacts the plunger. In some embodiments, two second sensors 464 are included for redundancy. When the second sensor 464 senses that the support portion 212 is in the closed position, the controller 480 may receive sensor data accordingly. The controller 480 may output an indication (e.g., to a GUI) indicative of whether the support portion 212 is in the closed position.

Referring to FIG. 4D, a fourth state 400D of operation of an example substrate loader and frame assembly is shown, according to aspects of the present disclosure. The door 240 may be actuated to the open position. In some embodiments, the controller 480 causes the door 240 to be actuated to the open position responsive to receiving sensor data indicating the presence and/or proper alignment of the substrate cassette 230, and that the support portion 212 is in the closed position. In some embodiments, when the door 240 is moved to the open position, the clamp 250 engages the cassette support 213 to lock the support portion 212 in the closed position. In some embodiments, a third sensor (not illustrated) may be configured to sense the position of the door 240 and/or the clamp 250. In some embodiments, the controller 480 receives sensor data (e.g., from the third sensor) indicating that the door 240 is in the open position. In some embodiments, the controller 480 causes a substrate-handling robot to retrieve and/or place substrates in the substrate cassette 230 through the door opening 224.

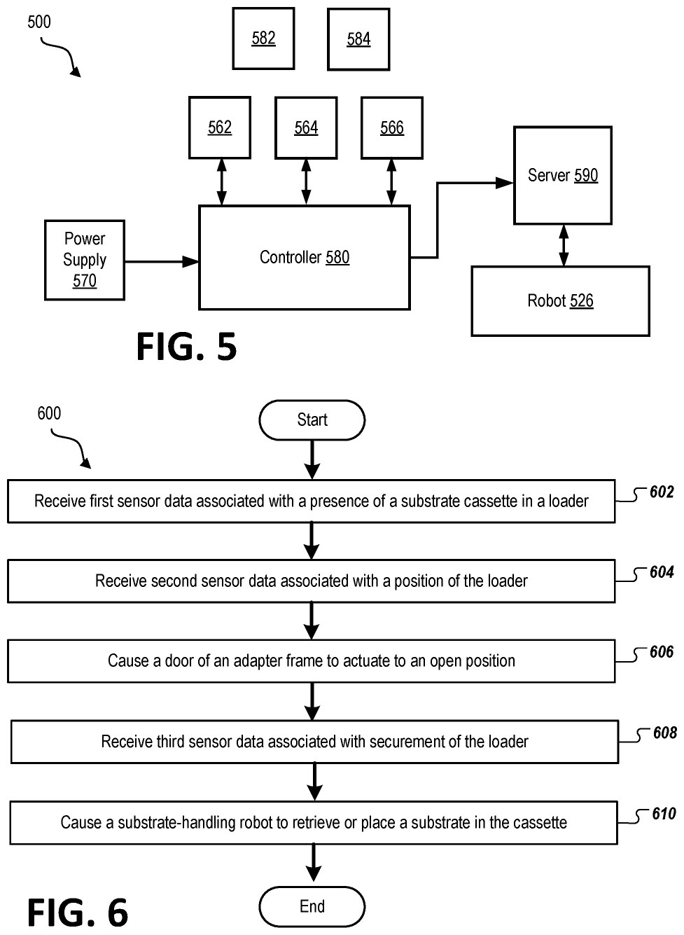

FIG. 5 is a simplified schematic diagram of an example control system 500 for a substrate processing system having an example substrate loader and frame assembly, according to aspects of the present disclosure. In some embodiments, a controller 580 (e.g., controller 480 of FIGS. 4A-4D) is provided with power by a power supply 570. The controller 580 may communicate with and/or cause operation of a robot 526 (e.g., a substrate-handling robot, etc.) via a server 590. Server 590 may be a server for controlling a substrate processing and/or manufacturing system. In some embodiments, controller 580 receives sensor data from a first sensor 562 (e.g., first sensor 462), a second sensor 564 (e.g., second sensor 464), and/or a third sensor 566. The sensors may be configured to sense conditions associated with the state of a substrate cassette loader and/or a frame door. In some embodiments, controller 580 outputs data to a status indicator 582 (e.g., of a GUI) and/or error indicator 585 (e.g., of the GUI).

In some embodiments, controller 580 outputs a status of the substrate loader and frame to the status indicator 582 based on sensor data received from the first sensor 562, the second sensor 564, and/or the third sensor 566. For example, the controller 580 may output data to the status indicator 582 indicative of the position of the presence or absence of a substrate cassette 230 on the cassette support 213, whether the substrate cassette 230 is properly aligned, the position (e.g., open or closed) of the support portion 212, and/or the position (e.g., open or closed) of the door 240. In some embodiments, status indicator 582 is an indicator on a GUI and/or an indicator light.

In some embodiments, controller 580 outputs an error of the substrate loader and frame to the error indicator 584 based on sensor data received from the first sensor 562, the second sensor 564, and/or the third sensor 566. For example, the controller 580 may output data to the error indicator 584 indicative of the misalignment of a substrate cassette 230 on the cassette support 213 or whether another error has occurred.

In some embodiments, the controller 580 sends instructions to the robot 526 (e.g., via server 590) to place or retrieve substrates in the substrate cassette 230 responsive to receiving sensor data from the first sensor 562 indicating the substrate cassette 230 is present and properly aligned on the cassette support 230, responsive to receiving sensor data from the second sensor 564 indicating the support portion 212 is in the closed position, and/or responsive to receiving sensor data from the third sensor 566 indicating the door 240 is in the open position and/or that the support portion 212 is locked in the closed position. By using sensor data from three sensors (e.g., 562, 564, and/or 566), system 500 includes three interlocks to prevent unintentional and/or accidental operation of the robot 526 which could result in damage to substrates or the robot itself.

FIG. 6 is a flow chart of a method 600 of operating an example substrate loader and frame assembly, according to aspects of the present disclosure. In some embodiments, method 600 is performed and/or caused to be performed by processing logic that includes hardware (e.g., circuitry, dedicated logic, programmable logic, microcode, processing device, etc.), software (such as instructions run on a processing device, a general purpose computer system, or a dedicated machine), firmware, microcode, or a combination thereof. In some embodiments, method 600 is performed, at least in part, by a controller of a substrate loader and frame (e.g., controller 480, controller 580, etc.).

For simplicity of explanation, method 600 is depicted and described as a series of operations. However, operations in accordance with this disclosure can occur in various orders and/or concurrently and with other operations not presented and described herein. Furthermore, in some embodiments, not all illustrated operations are performed to implement method 600 in accordance with the disclosed subject matter. In addition, those skilled in the art will understand and appreciate that method 600 could alternatively be represented as a series of interrelated states via a state diagram or events.

At block 602, processing logic receives first sensor data associated with a presence of a substrate cassette in a loader. For example, processing logic (e.g., of controller 480) may receive first sensor data (e.g., from sensor 462) indicating whether a substrate cassette 230 is present and/or aligned on cassette support 230.

At block 604, processing logic receives second sensor data associated with a position of the loader. For example, processing logic may receive second sensor data (e.g., from sensor 464) indicating whether the support portion 212 is in the closed position.

At block 606, processing logic causes a door of an adapter frame to actuate to an open position. The door may be caused to actuate (e.g., by an actuator) to the open position responsive to receiving sensor data indicating the substrate cassette is present and properly aligned and/or that the loader is in the closed position. For example, processing logic may cause the door 240 to be opened responsive to receiving sensor data from first sensor 462 indicating the substrate cassette 230 is present and aligned on the cassette support 230 and/or responsive to receiving sensor data from second sensor 464 indicating the support portion 212 is in the closed position.

At block 608, processing logic receives third sensor data associated with securement of the loader. The third sensor data may be provided by a third sensor that senses whether the loader has been secured in the closed position. Because the loader may be secured by a clamp (e.g., clamp 250) coupled to the door, the third sensor may sense the position of the door. The third sensor data may indicate the loader is secured when the door is in the open position. For example, processing logic may receive sensor data indicating the clamp 250 is in engagement with the cassette support 230, which indicates the support portion 212 is secured in the closed position. The sensor may sense the position of the door 240 and the securement of the support portion 212 by the clamp 250 may be inferred based on the position of the door 240.

At block 610, processing logic causes a substrate-handling robot to retrieve or place a substrate in the cassette. In some embodiments, processing logic causes a substrate-handling robot to retrieve or place a substrate in the cassette responsive to receiving the third sensor data (e.g., at block 608) indicating the loader is secured. By only initiating placement and/or retrieval of substrates in the cassette after receiving confirmation the loader is secured, unintentional substrate handling errors and/or substrate damage may be avoided.

The preceding description sets forth numerous specific details such as examples of specific systems, components, methods, and so forth in order to provide a good understanding of several embodiments of the present disclosure. It will be apparent to one skilled in the art, however, that at least some embodiments of the present disclosure can be practiced without these specific details. In other instances, well-known components or methods are not described in detail or are presented in simple block diagram format in order to avoid unnecessarily obscuring the present disclosure. Thus, the specific details set forth are merely exemplary. Particular implementations can vary from these exemplary details and still be contemplated to be within the scope of the present disclosure.

Reference throughout this specification to “one embodiment” or “an embodiment” means that a particular feature, structure, or characteristic described in connection with the embodiment is included in at least one embodiment. Thus, the appearances of the phrase “in one embodiment” or “in an embodiment” in various places throughout this specification are not necessarily all referring to the same embodiment. In addition, the term “or” is intended to mean an inclusive “or” rather than an exclusive “or.” When the term “about” or “approximately” is used herein, this is intended to mean that the nominal value presented is precise within ±10%.

Although the operations of the methods herein are shown and described in a particular order, the order of operations of each method can be altered so that certain operations can be performed in an inverse order so that certain operations can be performed, at least in part, concurrently with other operations. In another embodiment, instructions or sub-operations of distinct operations can be in an intermittent and/or alternating manner.

It is understood that the above description is intended to be illustrative, and not restrictive. Many other embodiments will be apparent to those of skill in the art upon reading and understanding the above description. The scope of the disclosure should, therefore, be determined with reference to the appended claims, along with the full scope of equivalents to which such claims are entitled.

What is claimed is:

1. A system, comprising:
a frame configured to couple to a factory interface, wherein the frame forms a door opening;
a substrate cassette loader supported by the frame, wherein the substrate cassette loader comprises:
a base portion coupled to the frame; and
a support portion, wherein the support portion is configured to support a substrate cassette, and wherein the support portion is configured to move between a first open position and a first closed position; and
a door configured to actuate between a second closed position and a second open position within the door opening, wherein when the door is in the second open position, one or more substrates in a cassette supported within the support portion are accessible via the door opening.

2. The system of claim 1, further comprising:
a clamp configured to lock the support portion in the first closed position while the door is in the second open position.

3. The system of claim 2, wherein the clamp is coupled to the door and engages the support portion while the door is in the second open position.

4. The system of claim 1, wherein the support portion is coupled to the base portion by a hinge, and wherein the support portion is configured to pivot with respect to the base portion between the first closed position and the first open position about an axis of the hinge.

5. The system of claim 4, wherein an interior of the support portion is accessible for placement or removal of the substrate cassette when the support portion is in the first open position.

6. The system of claim 1, further comprising:
one or more sensors configured to sense a presence of the substrate cassette within the support portion.

7. The system of claim 1, further comprising:
a sensor configured to sense when the support portion is in the first closed position.

8. The system of claim 1, further comprising:
a sensor configured to sense one or more of (i) when the door is in the second open position or (ii) when the support portion is locked in the first closed position.

9. The system of claim 1, further comprising:
a controller configured to cause actuation of the door between the second open position and the second closed position based on sensor data associated with the substrate cassette loader and the door.

10. The system of claim 1, wherein the factory interface is configured to handle 300 mm substrates, and wherein the substrate cassette is configured to hold 150 mm diameter or 200 mm diameter substrates.

11. A system, comprising:
an adapter frame configured to couple to a factory interface;
a substrate cassette loader supported by the frame;
a door configured to actuate between a first closed position and a first open position within a door opening formed by the adapter frame;
one or more sensors; and
a controller configured to cause actuation of the door based on sensor data received from the one or more sensors.

12. The system of claim 11, wherein the substrate cassette loader comprises:
a base portion coupled to a shelf of the frame; and
a support portion, wherein the support portion is configured to support a substrate cassette, wherein the support portion is configured to move between a second open position and a second closed position.

13. The system of claim 12, wherein an interior of the support portion is accessible for placement or removal of the substrate cassette when the support portion is in the second open position.

14. The system of claim 12, wherein the one or more sensors comprise one or more of:
at least one first sensor configured to sense a presence of the substrate cassette within the support portion;
a second sensor configured to sense when the support portion is in the second closed position; and
a third sensor configured to sense one or more of (i) when the door is in the first open position or (ii) when the support portion is locked in the second closed position.

15. The system of claim 12, further comprising:
a clamp configured to engage the support portion and lock the support portion in the second closed position while the door is in the first open position.

16. The system of claim 12, wherein the adapter frame is configured to adapt the factory interface for handling substrates having less than a threshold size, and wherein the substrate cassette is configured to hold 150 mm diameter or 200 mm diameter substrates.

17. A system, comprising:
a frame forming a door opening;
a substrate cassette loader coupled to the frame, wherein the substrate cassette loader comprises:
a base portion; and
a support portion configured to support a substrate cassette and further configured to move between a first open position and a first closed position;
a door configured to actuate between a second closed position and a second open position; and
a clamp coupled to the door and configured to engage the support portion and lock the support portion in the first closed position when the door is in the second open position.

18. The system of claim 17, wherein an interior of the support portion is accessible for placement or removal of the substrate cassette when the support portion is in the first open position.

19. The system of claim 17, further comprising:
one or more sensors configured to sense one or more conditions associated with at least one of the door or the substrate cassette loader.

20. The system of claim 19, further comprising:
a controller configured to cause actuation of the door based on sensor data received from the one or more sensors.
